(19) United States
(12) Patent Application Publication
(10) Pub. No.: US 2004/0007755 A1
(43) Pub. Date: Jan. 15, 2004

(54) Field oxide profile of an isolation region associated with a contact structure of a semiconductor device

(75) Inventors: Der-E Jan, Plano, TX (US); Binghua Hu, Plano, TX (US); Betty Shu Mercer, Plano, TX (US); Pushpa Mahalingam, Richardson, TX (US); Asadd M. Hosein, Plano, TX (US); John Kenneth Arch, Richardson, TX (US); C. Matthew Thompson, Highland Village, TX (US)

Correspondence Address: TEXAS INSTRUMENTS INCORPORATED, P O BOX 655474, M/S 3999, DALLAS, TX, 75265

(73) Assignee: Texas Instruments Incorporated

(21) Appl. No.: 10/193,959

(22) Filed: Jul. 12, 2002

(51) Int. Cl. H01L 29/00

(52) U.S. Cl. 257/506

(57) ABSTRACT

In one embodiment of the present invention, a contact structure of a semiconductor device within an integrated circuit includes an active region, the active region having been defined using a mask provided on a substrate. The contact structure further includes an isolation region adjacent the active region and including a field oxide: the field oxide having been grown by exposure of the substrate to a thermal process and an oxygen-containing gas; a film having been formed on a top surface of the mask during exposure to the thermal process and oxygen-containing gas; a dry etching process having been performed to substantially remove the film from the top surface of the mask and to remove a top portion of the field oxide in the isolation region; and a wet etching process having been performed to substantially remove any portion of the mask remaining after the dry etching process.

### BACKGROUND OF THE INVENTION

Integrated circuit fabrication often includes forming an isolation region that includes a field oxide and defines an active region of a semiconductor device. Forming the isolation region generally involves masking a silicon or other substrate over what is to be the active region and exposing the masked substrate to a thermal process and oxygen-containing gas. A reaction between the substrate material and the oxygen-containing gas causes the field oxide to grow on the unmasked portion of the substrate, thereby defining the active region. The mask covering the active region may also react with the oxygen-containing gas during exposure to the thermal process, causing a film to grow on a top surface of the mask. Furthermore, growth of the field oxide may extend underneath the mask from the sides to cause “bird's beak” regions to form in the field oxide near the edges of the mask, pushing up the edges of the mask and generating stress in the bird's beak regions of the field oxide. After growth of the field oxide, it is desirable to remove the film on the mask, a top portion of the field oxide in the isolation region, and the mask itself. Use of a wet etching process, such as one involving exposure to a dilute hydrofluoric acid solution, to remove the film from the mask and to remove the top portion of the field oxide in the isolation region may increase the sizes and aspect ratios of recesses near the bird's beak regions of the field oxide, particularly near the interface between the mask and the isolation region. Such recesses may be due, in part, to the stress generated in the bird's beak regions of the field oxide. After removal of the film on the mask, the top portion of the field oxide in the isolation region, and the mask itself, such recesses may trap residual particles or other materials during subsequent fabrication processes, which may lead to undesired filaments that cause the semiconductor device or the integrated circuit containing the semiconductor device to be defective. For example, an integrated circuit containing a semiconductor device with such filaments may short circuit. The problem may be exacerbated in certain devices requiring a relatively thick field oxide such as, for example, certain power devices and local oxidation of silicon (LOCOS) devices.

### SUMMARY OF THE INVENTION

According to the present invention, disadvantages and problems associated with previous techniques for growing a field oxide of an isolation region associated with a contact structure of a semiconductor device may be reduced or eliminated.

In one embodiment of the present invention, a contact structure of a semiconductor device within an integrated circuit includes an active region, the active region having been defined using a mask provided on a substrate. The contact structure further includes an isolation region adjacent the active region and including a field oxide: the field oxide having been grown by exposure of the substrate to a thermal process and an oxygen-containing gas; a film having been formed on a top surface of the mask during exposure to the thermal process and oxygen-containing gas; a dry etching process having been performed to substantially remove the film from the top surface of the mask and to remove a top portion of the field oxide in the isolation region; and a wet etching process having been performed to substantially remove any portion of the mask remaining after the dry etching process.

Particular embodiments of the present invention may provide one or more technical advantages. For example, certain embodiments may provide an improved field oxide profile of an isolation region associated with a contact structure of a semiconductor device. The improved field oxide profile may include a smaller recess with a smaller aspect ratio in the bird's beak regions of the field oxide than would be formed using previous techniques. A smaller recess may decrease or eliminate the trapping of residual particles or other materials during subsequent fabrication processes. As a result, the integrated circuit containing the semiconductor device may be less likely to include filaments that may cause failure, for example, due to a short circuit. Furthermore, the smaller recess may make subsequent fabrication steps easier, more reliable, or more effective. Certain embodiments of the present invention may be particularly beneficial for devices requiring a relatively thick field oxide such as, for example, certain power devices and LOCOS devices.

Systems and methods incorporating one or more of these or other technical advantages may be well suited for modern integrated circuit fabrication. Certain embodiments of the present invention may provide all, some, or none of the above advantages. Certain embodiments may provide one or more other technical advantages, one or more of which may be readily apparent to those skilled in the art from the figures, descriptions, and claims included herein.

### BRIEF DESCRIPTION OF THE DRAWINGS

For a more complete understanding of the present invention and features and advantages thereof, reference is now made to the following description, taken in conjunction with the accompanying drawings, in which:

FIGS. 1A-1E illustrate an example process for improving a field oxide profile of an isolation region associated with a contact structure of a semiconductor device; and

FIG. 2 illustrates an example method for improving the field oxide profile of an isolation region associated with a contact structure of a semiconductor device.

### DESCRIPTION OF EXAMPLE EMBODIMENTS

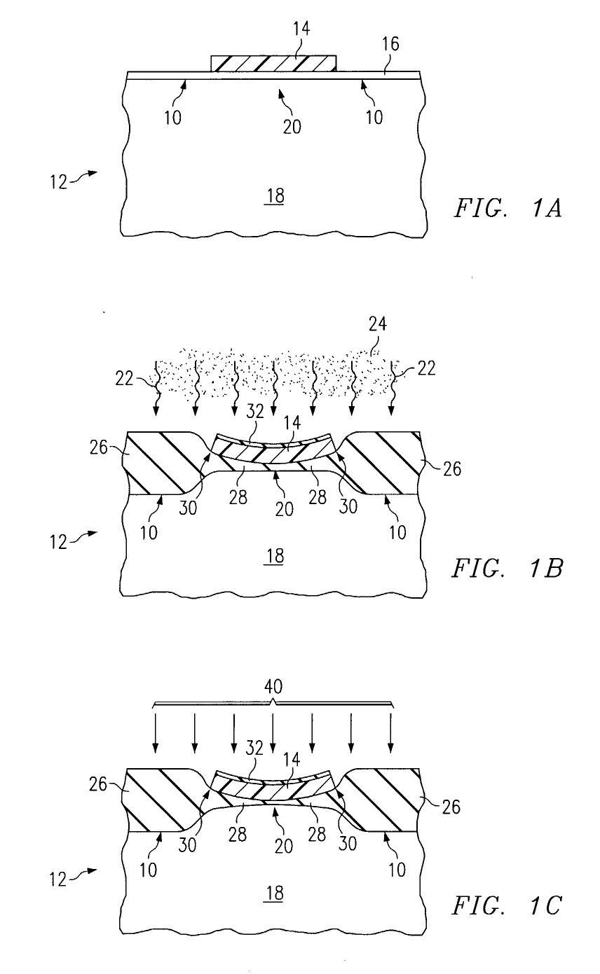

FIGS. 1A-1E illustrate an example process for improving a field oxide profile of an isolation region 10 associated with a contact structure 12 of a semiconductor device. As shown in FIG. 1A, a mask 14 may be provided on a thin pad oxide 16 grown on a silicon or other substrate 18. Mask 14 may define an active region 20 of the semiconductor device and may include silicon nitride (Si₃N₄) or any other material suitable for use as a mask. Mask 14 may be approximately 2000 Å thick, although the present invention contemplates mask 14 having any appropriate thickness according to particular needs. Pad oxide 16 substantially separates mask 14 from substrate 18 and may include silicon dioxide (SiO₂) or any other material suitable for use as a pad oxide. Pad oxide 16 may be approximately 150 Å thick, but the present invention contemplates pad oxide 16 having any appropriate thickness according to particular needs. Furthermore, the present invention contemplates fabricating the semiconductor device without the growth of pad oxide 16. If pad oxide 16 is not grown, mask 14 may be provided directly on substrate 18 to define active region 20.

As shown in FIG. 1B, substrate 18 may be exposed to a thermal process 22 and an oxygen-containing gas 24 (for example, steam) to grow a field oxide 26, primarily in isolation region 10 due to the presence of mask 14. Exposing substrate 18 to thermal process 22 may include heating substrate 18 to approximately 950° C. or any other suitable temperature according to particular needs. The duration of exposure to thermal process 22 and oxygen-containing gas 24 may determine the thickness of field oxide 26. For example, the longer substrate 18 is exposed to thermal process 22 and oxygen-containing gas 24, the thicker field oxide 26 may grow. In a particular embodiment, field oxide 26 is grown approximately 6200 Å thick, although the present invention contemplates field oxide 26 having any suitable thickness according to particular needs. In one embodiment, substrate 18 includes silicon, which may chemically react with oxygen-containing gas 24 during exposure to thermal process 22 to “oxidize” substrate 18 in isolation region 10 and grow a silicon dioxide field oxide 26. Substrate 18 may, however, include any suitable material and may react with oxygen-containing gas 24 to form any suitable field oxide 26.

During growth of field oxide 26, a portion of field oxide 26 may extend underneath mask 14 from the sides into active region 20, pushing up the edges of mask 14 and forming “bird's beak” regions 28 and associated recesses 30 in field oxide 26 near the edges of mask 14. The presence of bird's beak regions 28 and mask 14 may generate stress in bird's beak regions 28 of field oxide 26. In certain embodiments, lengthening bird's beak regions 28 further into active region 20 and reducing the thickness of bird's beak regions 28 may reduce such stress in bird's beak regions 28. For example, including pad oxide 16 may allow the material of field oxide 26, when reacting with oxygen-containing gas 24 during exposure to thermal process 22, to form bird's beak regions 28 that extend further into active region 20. Furthermore, as the thickness of pad oxide 16 increases, the further bird's beak regions 28 may extend into active region 20, possibly reducing the stress in bird's beak regions 28.

During exposure to thermal process 22 and oxygen-containing gas 24, a thin film 32 may form on a top surface of mask 14. In one embodiment, mask 14 includes silicon nitride (Si₃N₄), which may chemically react with oxygen-containing gas 24 during exposure to thermal process 22 to grow a film 32 that includes “oxynitride” (Siₓ—O_{y}—N_{z}, where x, y, and z may be any suitable numbers, depending on the elements or compounds involved in the chemical reaction). Furthermore, within film 32, there may be a high concentration of oxygen near the top of film 32. The thickness of film 32 may be determined by the duration of exposure to thermal process 22 and oxygen-containing gas 24, which may be selected according to a desired thickness for field oxide 26. For example, as the desired thickness of field oxide 26 increases, the duration of exposure to thermal process 22 and oxygen-containing gas 24 may also increase, thereby increasing the thickness of film 32. Film 32 may be approximately 150 Å to approximately 200 Å thick, although the present invention contemplates film 32 having any suitable thickness according to particular needs. As just one example, if mask 14 is 2000 Å thick before exposure to thermal process 22 and oxygen-containing gas 24, exposure to thermal process 22 and oxygen-containing gas 24 may cause the material within a top portion of mask 14 to react with oxygen-containing gas 24 such that film 32 is approximately 200 Å thick and the remaining unreacted portion of mask 14 is approximately 1800 Å thick.

As one of the steps during fabrication of an integrated circuit containing the semiconductor device, it may be necessary to substantially remove film 32 and to remove a top portion of field oxide 26 in isolation region 10. The top portion of field oxide 26 to be removed from isolation region 10 may be approximately 300 Å thick, although the present invention contemplates removing any appropriate thickness of field oxide 26 according to particular needs. Current techniques for removing film 32 the top portion of field oxide 26 include exposure to a wet etching process that may increase the sizes and aspect ratios of recesses 30 near bird's beak regions 28 of field oxide 26, particularly near the interface between mask 14 and isolation region 10.

As an example, film 32 may include oxynitride, field oxide 26 may include silicon dioxide, and film 32 and field oxide 26 may be exposed to a dilute hydrofluoric acid (HF) solution to remove film 32 and field oxide 26. For example, the dilute hydrofluoric acid solution may include one hundred parts water and one part 49% hydrofluoric acid to achieve a 0.49% concentration of hydrofluoric acid in the dilute hydrofluoric acid solution. In this example, the etch rate of the silicon dioxide field oxide 26 using the dilute hydrofluoric acid solution is known to range from approximately 27 Å per minute to approximately 30 Å per minute. It may be difficult to determine the etch rate of the oxynitride film 32, however, because the etch rate may vary according to the oxygen content of the oxynitride film 32. However, in one embodiment it may be assumed that the oxynitride film 32 is stripped at approximately the same rate as the silicon dioxide field oxide 26 (from approximately 27 Å per minute to approximately 30 Å per minute).

Due in part to the isotropic properties of typical wet etching solutions (i.e. the wet etching solutions etch substantially equivalently in all directions), not only may the oxynitride film 32 be substantially completely removed, but the top portion of the silicon dioxide field oxide 26 removed may be thicker than desired. The presence of bird's beak regions 28 may also contribute to the over-etching of field oxide 26. As discussed above, there is stress in bird's beak regions 28 of field oxide 26. The etch rate in bird's beak regions 28 of field oxide 26 may increase as a result of this stress. Thus, the isotropic wet etching solution may etch at a faster rate in bird's beak regions 28 of field oxide 26 than in other regions of field oxide 26, increasing the sizes and aspect ratios of recesses 30 near bird's beak regions 28 of field oxide 26, particularly near the interface between mask 14 and isolation region 10. After removal of film 32, the top portion of field oxide 26, and later mask 14 itself, recesses 30 may trap residual particles or other materials during later fabrication steps, which may lead to undesired filaments that may cause the semiconductor device or the integrated circuit containing the semiconductor device to be defective. For example, an integrated circuit containing a semiconductor device with such filaments may short circuit. The problem may be exacerbated in certain devices requiring a relatively thick field oxide such as, for example, certain power devices and LOCOS devices.

Alternatively, as shown in FIG. 1C, the present invention may involve exposure to a dry etching process 40 to substantially remove film 32 from the top surface of mask 14 and to remove a top portion of field oxide 26 in isolation region 10. Dry etching process 40 may include a plasma etching process such as a plasma de-glaze or plasma oxynitride etch step for example. The plasma etching process may include inert ions, hydrogen ions, a gas such as CF₄ (“Freon 14”), or any other suitable materials according to particular needs. Although a plasma etching process is described, any suitable dry etching process 40 may be used according to particular needs. Dry etching process 40 may target the removal of any suitable thickness of film 32 and any suitable thickness of field oxide 26. In one embodiment, it may be desirable to remove substantially all of film 32, and the top portion of field oxide 26 to be removed may be approximately 300 Å thick.

As just one example, field oxide 26 may be approximately 6200 Å thick and film 32 may be approximately 200 Å thick. In this example, dry etching process 40 may include a plasma etching process that includes Freon 14. The plasma etching process may target the removal of all approximately 200 Å of film 32 and approximately 300 Å of field oxide 26. Furthermore, the plasma etching process may remove a top portion of mask 14 underlying film 32. In one embodiment, the plasma etching process may be performed under the following conditions: a bottom electrode temperature of approximately −15° C.; a pressure of approximately 700 mtorr; a radio frequency (RF) power of approximately 125 Watts; and a duration of approximately eighteen seconds.

Unlike the wet etching process used in previous techniques, which as described above is substantially isotropic, dry etching process 40 according to the present invention may be substantially anisotropic, such that it removes materials in substantially only one direction (i.e. vertically). The anisotropic characteristic of dry etching process 40 may decrease the formation or the increase in sizes and aspect ratios of recesses 30 near bird's beak regions 28 of field oxide 26 by decreasing or eliminating undercutting or etch-back near bird's beak regions 28, at the interface between mask 14 and isolation region 10 for example. In a particular embodiment, the depth of recesses 30 formed in field oxide 26 during exposure to dry etching process 40 is at least approximately forty percent less than the depth of recesses 30 formed during exposure to the wet etching process of previous techniques. However, the present invention is intended to encompass reduction of the sizes and aspect ratios of recesses 30 to any extent.

As shown in FIG. 1D, following exposure to dry etching process 40, a wet etching process 42 may substantially remove the remaining portion of mask 14. In one embodiment, where none of the unreacted portion of mask 14 is removed during exposure to dry etching process 40, the remaining portion of mask 14 is the entire unreacted portion of mask 14. Wet etching process 42 may include exposure to a phosphoric acid solution or any other suitable wet etching solution according to particular needs. As shown in FIG. 1E, contact structure 12 may include an improved field oxide profile with smaller recesses 30 near bird's beak regions 28 of field oxide 26.

Particular embodiments of the present invention may provide one or more technical advantages. For example, certain embodiments may provide an improved field oxide 26 profile of isolation region 10 associated with contact structure 12 of the semiconductor device. Improved field oxide 26 profile may include smaller recesses 30 each with a smaller aspect ratio in bird's beak regions 28 of field oxide 26 than would be formed using previous techniques. Smaller recesses 30 may decrease or eliminate the trapping of residual particles or other materials during subsequent fabrication processes. As a result, the integrated circuit containing the semiconductor device may be less likely to include filaments that may cause failure, for example, due to a short circuit. Furthermore, smaller recesses 30 may make subsequent fabrication steps easier, more reliable, or more effective. Certain embodiments of the present invention may be particularly beneficial for devices requiring a relatively thick field oxide 26 such as, for example, certain power devices and LOCOS devices.

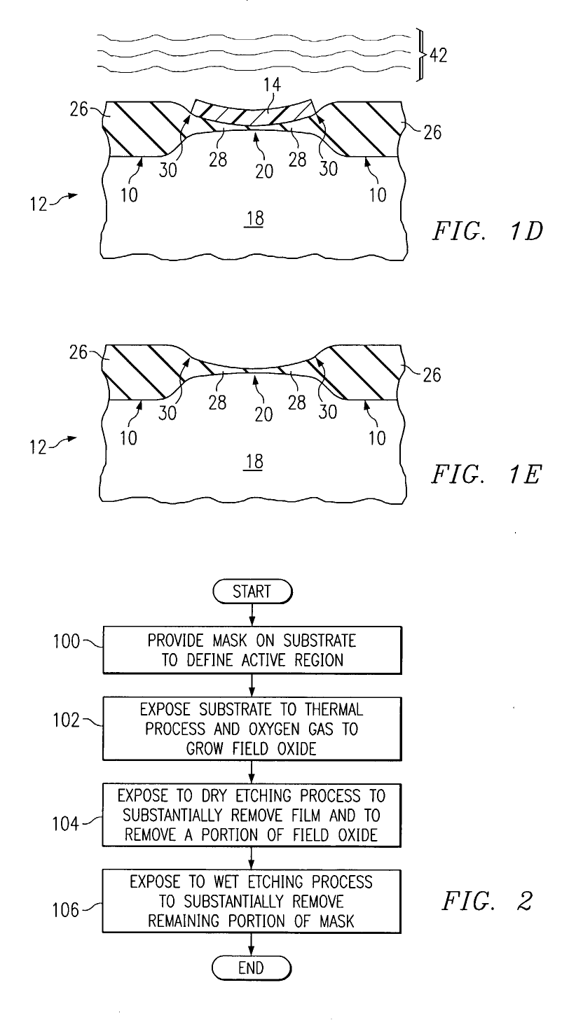

FIG. 2 illustrates an example process for improving a field oxide profile of isolation region 10 associated with contact structure 12 of a semiconductor device. At step 100, mask 14 may be provided on substrate 18 to define active region 20. In one embodiment, pad oxide 16 substantially separates mask 14 from substrate 18. At step 102, substrate 18 may be exposed to thermal process 22 and oxygen-containing gas 24 to grow field oxide 26, primarily in isolation region 10 due to the presence of mask 14. During step 102, a portion of field oxide 26 may extend underneath mask 14 from the sides into active region 20, pushing up the edges of mask 14 and forming bird's beak regions 28 and associated recesses 30 in field oxide in field oxide 26 near the edges of mask 14. Furthermore, during step 102, thin film 32 may form on the top surface of mask 14. At step 104, exposure to dry etching process 40 may substantially remove film 32 and remove a top portion of field oxide 26 in isolation region 10. As compared with previous wet etching techniques, dry etching process 40 reduces the sizes and aspect ratios of recesses 30 near bird's beak regions 28 of field oxide 26, thereby improving the field oxide profile of isolation region 10. Dry etching process 40 may be a plasma etching process or any other suitable dry etching process. In a particular embodiment, the depth of recesses 30 formed in field oxide 26 during exposure to dry etching process 40 is at least approximately forty percent less than the depth of recesses 30 formed during exposure to the wet etching process of previous techniques. However, as discussed above, the present invention is intended to encompass reduction of the sizes or aspect ratios of recesses 30 to any extent. At step 106, wet etching process 42 may substantially remove the remaining portion of mask 14, and the method ends.

Although the present invention has been described with several embodiments, diverse changes, substitutions, variations, alterations, and modifications may be suggested to one skilled in the art, and it is intended that the invention encompass all such changes, substitutions, variations, alterations, and modifications as fall within the spirit and scope of the appended claims.

What is claimed is:

1. An integrated circuit comprising a contact structure of a semiconductor device, the contact structure comprising:
an active region, the active region having been defined using a mask provided on a substrate; and
an isolation region adjacent the active region and comprising a field oxide:
the field oxide having been grown by exposure of the substrate to a thermal process and an oxygen-containing gas;
a film having been formed on a top surface of the mask during exposure to the thermal process and the oxygen-containing gas;
a dry etching process having been performed to substantially remove the film from the top surface of the mask and to remove a top portion of the field oxide in the isolation region; and
a wet etching process having been performed to substantially remove any portion of the mask remaining after the dry etching process.

2. The integrated circuit of claim 1, wherein the film has been substantially removed from the top surface of the mask and the top portion of the field oxide in the isolation region has been removed independent of any wet etching process.

3. The integrated circuit of claim 1, wherein the dry etching process to substantially remove the film from the top surface of the mask and to remove the top portion of the field oxide in the isolation region comprises a plasma etching process.

4. The integrated circuit of claim 3, wherein the plasma etching process has been performed with a bottom electrode temperature of −15° C., a pressure of 700 mtorr, and a radio frequency (RF) power of 125 Watts for a duration of eighteen seconds using a gas comprising CF₄ (Freon 14).

5. The integrated circuit of claim 1, wherein the dry etching process to substantially remove the film from the top surface of the mask and to remove the top portion of the field oxide in the isolation region comprises a substantially anisotropic dry etching process, the dry etching process etching the film and the top portion of the field oxide at substantially the same rate.

6. The integrated circuit of claim 1, wherein the field oxide extends underneath the mask into the active region, pushing up an edge of the mask and forming a “bird's beak” region of the field oxide, a recess having been formed near the bird's beak region of the field oxide during the dry etching process, the recess having a depth as a result of the dry etching process that is less than if a wet etching process had been used to substantially remove the film from the top surface of the mask and to remove the top portion of the field oxide in the isolation region.

7. The integrated circuit of claim 6, wherein performing the dry etching process rather than a wet etching process to substantially remove the film from the top surface of the mask and to remove the top portion of the field oxide in the isolation region substantially reduces etch-back or undercutting of the field oxide in the bird's beak region.

8. The integrated circuit of claim 6, wherein the depth of the recess formed during the dry etching process is at least approximately forty percent less than if a wet etching process had been used to substantially remove the film from the top surface of the mask and to remove the top portion of the field oxide in the isolation region.

9. The integrated circuit of claim 1, wherein the integrated circuit comprises one or more filaments formed between the contact structure and one or more other contact structures, the filaments being fewer in number than if a wet etching process had been used to substantially remove the film from the top surface of the mask and to remove the top portion of the field oxide in the isolation region.

10. The integrated circuit of claim 1, wherein:
the field oxide comprises silicon dioxide;
the mask comprises silicon nitride;
the film comprises oxynitride; and
the wet etching process to substantially remove any portion of the mask remaining after the dry etching process comprises exposure to phosphoric acid.

11. A method for improving a field oxide profile of an isolation region associated with a contact structure of a semiconductor device within an integrated circuit, comprising:
providing a mask on a substrate to define an active region of the semiconductor device;
exposing the substrate to a thermal process and an oxygen-containing gas to grow a field oxide to define an isolation region adjacent the active region and comprising the field oxide, a film being formed on a top surface of the mask during exposure to the thermal process and the oxygen-containing gas;
performing a dry etching process to substantially remove the film from the top surface of the mask and to remove a top portion of the field oxide in the isolation region; and
performing a wet etching process to substantially remove any portion of the mask remaining after the dry etching process.

12. The method of claim 11, wherein substantially removing the film from the top surface of the mask and removing the top portion of the field oxide in the isolation region occur independent of any wet etching process.

13. The method of claim 11, wherein the dry etching process to substantially remove the film from the top surface of the mask and to remove the top portion of the field oxide in the isolation region comprises a plasma etching process.

14. The method of claim 13, wherein the plasma etching process has been performed with a bottom electrode temperature of −15° C., a pressure of 700 mtorr, and a radio frequency (RF) power of 125 Watts for a duration of eighteen seconds using a gas comprising CF₄ (Freon 14).

15. The method of claim 11, wherein the dry etching process to substantially remove the film from the top surface of the mask and to remove the top portion of the field oxide in the isolation region comprises a substantially anisotropic dry etching process, the dry etching process etching the film and the top portion of the field oxide at substantially the same rate.

16. The method of claim 11, wherein the grown field oxide extends underneath the mask into the active region, pushing up an edge of the mask and forming a “bird's beak” region of the field oxide, a recess being formed near the bird's beak region of the field oxide during the dry etching process, the recess having a depth as a result of the dry etching process that is less than if a wet etching process had been used to substantially remove the film from the top surface of the mask and to remove the top portion of the field oxide in the isolation region.

17. The method of claim 16, wherein performing the dry etching process rather than a wet etching process to substantially remove the film from the top surface of the mask and to remove the top portion of the field oxide in the isolation region substantially reduces etch-back or undercutting of the field oxide in the bird's beak region.

18. The method of claim 16, wherein the depth of the recess formed during the dry etching process is at least approximately forty percent less than if the wet etching process had been used to substantially remove the film from the top surface of the mask and to remove the top portion of the field oxide in the isolation region.

19. The method of claim 11, wherein one or more filaments are formed between the contact structure and one or more other contact structures, the filaments being fewer in number than if a wet etching process had been used to substantially remove the film from the top surface of the mask and to remove the top portion of the field oxide in the isolation region.

20. The method of claim 1 1, wherein:
the field oxide comprises silicon dioxide;
the mask comprises silicon nitride;
the film comprises oxynitride; and
the wet etching process to substantially remove any portion of the mask remaining after the dry etching process comprises exposure to phosphoric acid.

21. An integrated circuit comprising a contact structure of a semiconductor device, the contact structure comprising:
an active region, the active region having been defined using a mask provided on a substrate; and
an isolation region adjacent the active region and comprising a field oxide:
the field oxide having been grown by exposure of the substrate to a thermal process and an oxygen-containing gas, the field oxide extending underneath the mask into the active region, pushing up an edge of the mask and forming a “bird's beak” region of the field oxide;
a film having been formed on a top surface of the mask during exposure to the thermal process and the oxygen-containing gas;
a dry plasma etching process having been performed to substantially remove the film from the top surface of the mask and to remove a top portion of the field oxide in the isolation region, the film having been substantially removed from the top surface of the mask and the top portion of the field oxide in the isolation region having been removed independent of any wet etching process, performance of the dry plasma etching process rather than a wet etching process to substantially remove the film from the top surface of the mask and to remove the top portion of the field oxide in the isolation region having substantially reduced etch-back or undercutting of the field oxide in the bird's beak region such that a recess formed near the bird's beak region of the field oxide during the dry plasma etching process is smaller than if a wet etching process had been used to substantially remove the film from the top surface of the mask and to remove the top portion of the field oxide in the isolation region; and
a wet etching process having been performed to substantially remove any portion of the mask remaining after the dry plasma etching process.

22. A method for improving a field oxide profile of an isolation region associated with a contact structure of a semiconductor device within an integrated circuit, comprising:
providing a mask on a substrate to define an active region of the semiconductor device;
exposing the substrate to a thermal process and an oxygen-containing gas to grow a field oxide to define an isolation region adjacent the active region and comprising the field oxide, the field oxide extending underneath the mask into the active region, pushing up an edge of the mask and forming a “bird's beak” region of the field oxide, a film being formed on a top surface of the mask during exposure to the thermal process and the oxygen-containing gas;
performing a dry plasma etching process to substantially remove the film from the top surface of the mask and to remove a top portion of the field oxide in the isolation region, the film being substantially removed from the top surface of the mask and the top portion of the field oxide in the isolation region being removed independent of any wet etching process, performance of the dry plasma etching process rather than a wet etching process to substantially remove the film from the top surface of the mask and to remove the top portion of the field oxide in the isolation region substantially reducing etch-back or undercutting of the field oxide in the bird's beak region such that a recess formed near the bird's beak region of the field oxide during the dry plasma etching process is smaller than if a wet, etching process had been used to substantially remove the film from the top surface of the mask and to remove the top portion of the field oxide in the isolation region; and
performing a wet etching process to substantially remove any portion of the mask remaining after the dry plasma etching process.
